(19) United States
(12) Patent Application Publication
(10) Pub. No.: US 2003/0023946 A1
(43) Pub. Date: Jan. 30, 2003

(54) Standard cell library generation using merged power method

(76) Inventors: Ming-Te Lin, Chutung (TW); Tsuoe-Hsiang Liao, Hsinchu (TW)

Correspondence Address: CHARLES C.H. WU & ASSOCIATES, Suite 710, 7700 IRVINE CENTER DRIVE, Irvine, CA, 92618-3043, US

(21) Appl. No.: 09/921,415

(22) Filed: Aug. 2, 2001

(30) Foreign Application Priority Data
Jul. 24, 2001 (TW) 90118010

(51) Int. Cl. G06F 17/50; H03K 19/00

(52) U.S. Cl. 716/17; 716/9

(57) ABSTRACT

A cell arrangement scheme is disclosed. A first cell comprising a PMOS and a NMOS, wherein the source of the PMOS is connected with a power line VDD by a first metal line, the source of the NMOS is connected to a power line GND by a second, the drains of the PMOS and NMOS connected together by a third metal line, and the gate of the PMOS and the NMOS are connected together by a poly line. A second cell comprising a PMOS and a NMOS, wherein the source of the PMOS is connected with a power line VDD by a first metal line, the source of the NMOS is connected to a power line GND by a second metal line, the drains of the PMOS and NMOS connected together by a third metal line, and the gate of the PMOS and the NMOS are connected together by a poly line. Partially overlapping the first cell in a such a way that the first and the second metal line of the first cell is overlapped and in contact with the first and the second metal line of the second cell respectively. The cells are positioned so as to minimize the block size so that the total area of the layout can be minimized.

### CROSS-REFERENCE TO RELATED APPLICATION

This application claims the priority benefit of Taiwan application serial no. 90118010, filed Jul. 24, 2001.

### BACKGROUND OF THE INVENTION

1. Filed of Invention

The present invention relates generally to a design and manufacture of a semiconductor device and more specifically to a method of generating cell library using a merged power method.

2. Description of Related Art

A common method of designing an integrated circuit (IC) in a semiconductor design requires a library of computer stored circuit cells and a behavioral circuit model describing the functionality of the integrated circuit. The circuit cells typically include fundamental logic gates such as OR, NAND, NOR, AND, XOR, inverter, and like logical cells with an array of logic gate sizes. These cells also include sequential circuit elements such as latches and flip-flops for memory requirements. Then determining interconnects for the selected cells, and then placing and routing the interconnected selected cells to form the integrated circuit. For example, groups of cells may be interconnected into a block to function as flip-flops, shift registers and the like. This process, overall, is conventionally described in terms of logic description, synthesis of that logic, and then placement and routing of the synthesized logic.

With recent advances in processing and designing technology, LSIs (Large-Scale Integrated Circuits) represented by a microprocessor have been increasing rapidly in performance and integration. Currently, the minimum geometric feature size of a component is on the order of 0.5 microns. However, it is expected that the feature size can be reduced to 0.1 micron within several years. This small feature size allows fabrication of as many as 4.5 million transistors or 1 million gates of logic on a 25 millimeter by 25 millimeter chip. This trend is expected to continue, with even smaller feature geometries and more circuit elements on an integrated circuit, and of course, larger die (or chip) sizes will allow far greater numbers of circuit elements.

Due to the large number of components and the exacting details required by the fabrication process, physical design is not practical without the aid of computers. As a result, most phases of physical design extensively use Computer Aided Design (CAD) tools, and many phases have already been partially or fully automated. Automation of the physical design process has increased the level of integration, reduced turn around time and enhanced chip performance.

To implement the LSIs with higher performance and higher integration, it is required to perform circuit design with higher accuracy so that CAD (Computer Aided Design) tools have been playing an important role in high-accuracy circuit design.

The layout is then checked to ensure that it meets all of the design requirements. The result is a set of design files in a particular unambiguous representation known as an intermediate form that describes the layout. The design files are then converted into pattern generator files that are used to produce patterns called masks by an optical or electron beam pattern generator.

During fabrication, these masks are used to pattern a silicon wafer using a sequence of photolithographic steps. The component formation requires very exacting details about geometric patterns and separation between them. The process of converting the specifications of an electrical circuit into a layout is called the physical design. It is an extremely tedious and an error-prone process because of the tight tolerance requirements and the minuteness of the individual components.

The objective of physical design is to determine an optimal arrangement of devices in a plane or in a three dimensional space, and an efficient interconnection or routing scheme between the devices to obtain the desired functionality. Since space on a wafer is very expensive real estate, algorithms must use the space very efficiently to lower costs and improve yield.

Currently available physical design automation systems are limited in that they are only capable of placing and routing approximately 20,000 devices or cells. Placement of larger numbers of cells is accomplished by partitioning the cells into blocks of 20,000 or less, and then placing and routing the blocks. This expedient is not satisfactory since the resulting placement solution is far from optimal since the integrated circuit comprises a large number cells, which can be tens of thousands, hundreds of thousands or even millions or more of small cells. Each cell represents a single logic element, such as a gate, or several logic elements that are interconnected in a standardized manner to perform a specific function. Cells that consist of two or more interconnected gates or logic elements are also available as standard modules in circuit libraries.

The cells and the other elements of the circuit described above are interconnected or routed in accordance with the logical design of the circuit to provide the desired functionality. The various elements of the circuit are interconnected by electrically conductive lines or traces that are routed, for example, through vertical channels and horizontal channels that run between the cells.

The input to the physical design problem is a circuit diagram, and the output is the layout of the circuit. This is accomplished in several stages including partitioning, floor planning, placement, routing and compaction.

Partitioning—A chip may contain several million transistors. Layout of the entire circuit cannot be handled due to the limitation of memory space as well as the computation power available. Therefore it is normally partitioned by grouping the components or cells into blocks such as subcircuits and modules. The interconnection between the cells is accompliched by interconnect wires which is complex and time consuming and requires physical placements. The actual partitioning process considers many factors such as the size of the blocks, number of blocks and number of interconnections between the blocks.

The output of partitioning is a set of blocks, along with the interconnections required between blocks. The set of interconnections required is referred to as a netlist. In large circuits, the partitioning process is often hierarchical, although non-hierarchical (e.g. flat) processes can be used, and at the topmost level a circuit can have between 5 to 25 blocks. However, greater numbers of blocks are possible and contemplated. Each block is then partitioned recursively into smaller blocks.

Floor planning and placement—This step is concerned with selecting good layout alternatives for each block of the entire chip, as well as between blocks and to the edges. Floor planning is a critical step as it sets up the ground work for a good layout. However it is computationally quite hard. Very often the task of floor plan layout is done by a design engineer using a CAD tool. This is necessary as the major components of an IC are often intended for specific locations on the chip.

Only for simple layouts can the current layout tools provide a solution without human-engineering direction and intervention. One aspect of the present invention will permit complex problems, including flow plan layout, to be accomplished without regular human intervention.

During placement, as shown in FIG. 1, group of cells 66 are arranged and interconnected to form a block 60 and a number of such blocks are exactly positioned on the chip (not shown). The goal of placement is to find a minimum area arrangement for the blocks that allows completion of interconnections between the blocks. Placement is typically done in two phases. In the first phase, an initial placement is created. In the second phase, the initial placement is evaluated and iterative improvements are made until the layout has minimum area and conforms to design specifications.

To limit the number of iterations of the placement algorithm, an estimate of the required routing space is used during the placement phase. A good routing and circuit performance heavily depend on a good placement algorithm. This is due to the fact that once the position of each block is fixed, very little can be done to improve the routing and overall circuit performance.

Routing—The objective of the routing phase is to complete the interconnections between blocks according to the specified netlist. First, the space not occupied by blocks, which is called the routing space, is partitioned into rectangular regions called channels and switch boxes. The goal of a router is to complete all circuit connections using the shortest possible wire length and using only the channel and switch boxes.

Routing is usually done in two phases referred to as the global routing and detailed routing phases. In global routing, connections are completed between the proper blocks of the circuit disregarding the exact geometric details of each wire and terminal. For each wire, a global router finds a list of channels that are to be used as a passageway for that wire. In other words, global routing specifies the loose route of a wire through different regions of the routing space.

Global routing is followed by detailed routing which completes point-to-point connections between terminals on the blocks. Loose routing is converted into exact routing by specifying the geometric information such as width of wires and their layer assignments. Detailed routing includes channel routing and switch box routing.

Due to the nature of the routing algorithms, complete routing of all connections cannot be guaranteed in many cases. As a result, a technique called “rip up and re-route” is used that removes troublesome connections and re-routes them in a different order.

Compaction—Compaction is the task of compressing the layout in all directions such that the total area is reduced. By making the chips smaller, wire lengths are reduced which in turn reduces the signal delay between components of the circuit. At the same time a smaller area enables more chips to be produced on a wafer which in turn reduces the cost of manufacturing. Compaction must ensure that no rules regarding the design and fabrication process are violated.

VLSI physical design is iterative in nature and many steps such as global routing and channel routing are repeated several times to obtain a better layout. In addition, the quality of results obtained in one stage depends on the quality of solution obtained in earlier stages as discussed above. For example, a poor quality placement cannot be fully cured by high quality routing. As a result, earlier steps have extensive influence on the overall quality of the solution.

In this sense, partitioning, floor planning and placement problems play a more important role in determining the area and chip performance in comparison to routing and compaction. Since placement may produce an unroutable layout, the whole the chip might need to be replaced or re-partitioned by removing defective block(s) and replacing with new block(s) before another routing is attempted. The whole design cycle is conventionally repeated several times to accomplish the design objectives. The complexity of each step varies depending on the design constraints as well as the design style used.

Therefore it is highly desirable to improve so that a semiconductor circuit design can be more accurately and the design and routing can be accomplished in a comparatively shorter time and whereby the yield and the through-put can be substantially increased. Accordingly, in order to meet the above object, the present invention provides a simple and reliable.

### SUMMARY OF THE INVENTION

The present invention provides a physical placement method of cells whereby the total area of the layout can be substantially reduced.

The present invention provides an accurate and effective IC layout design scheme whereby the yield and the through-put is substantially increased.

The present invention provides a method for generating the cell library by merging the power line of a cell with the power line of an adjacent cell whereby the wire connection between the cells are eliminated, therefore the complexity of making the wire connection between cells can be effectively eliminated.

The present invention provides an IC layout design scheme whereby the overall designing and routing time can be effectively reduced. Therefore the through-put can be substantially increased. Therefore the overall cost of the IC fabrication can be substantially reduced.

Accordingly, in order to meet the above objects, the present invention provides an effective and simple cell arrangement scheme. A first cell comprising a PMOS and a NMOS, wherein the source of the PMOS is connected with a power line VDD by a first metal line, the source of the NMOS is connected to a power line GND by a second metal line, the drains of the PMOS and NMOS connected together by a third metal line, and the gate of the PMOS and the NMOS are connected together by a poly line. A second cell comprising a PMOS and a NMOS, wherein the source of the PMOS is connected with a power line VDD by a first metal line, the source of the NMOS is connected to a power line GND by a second metal line, the drains of the PMOS and NMOS connected together by a third metal line, and the gate of the PMOS and the NMOS are connected together by a poly line. Partially overlapping the first cell in a such a way that the first and the second metal line of the first cell is overlapped and in contact with the first and the second metal line of the second cell respectively. The cells are positioned so as to minimize the block size so that the total area of the layout can be minimized.

It is to be understood by those skilled in the art that because the cells are partially overlapped, therefore, the total area of the layout can be substantially reduced.

It is to be understood by those skilled in the art that because the wire connection between the cells are eliminated, therefore the complexity of making the wire connection between cells can be effectively eliminated.

It is to be understood by those skilled in the art that because the complexity of making the wire connections between the cells are eliminated, therefore the risk of faulty connections between the cells can be eliminated, thus the yield can be substantially increased.

It is to be understood by those skilled in the art that because the wire connections between the cells are eliminated, therefore the time and the total wire length can be substantially reduced. Therefore, the overall IC design time can be substantially reduced. Therefore the through-put can be substantially increased. Therefore the overall cost of the IC fabrication can be substantially reduced.

It is understood that the foregoing general description and the following detailed description are exemplary, but are not restrictive, of the invention.

### BRIEF DESCRIPTION OF THE DRAWING

The invention is best understood from the following detailed description when read in connection with the accompanying drawing. Included in the drawing are the following figures:

FIG. 1 is a schematic, showing the convention cell arrangement scheme;

FIG. 2 is a schematic, showing a typical inverter cell in accordance with a preferred embodiment of the present invention;

FIG. 3 is a schematic, showing a typical inverter cell in accordance with a preferred embodiment of the present invention; and

FIG. 4 is a schematic, showing the partial overlap between two inverter cells by using the merged power method, in accordance with a preferred embodiment of the present invention.

### DESCRIPTION OF THE PREFERRED EMBODIMENTS

Reference will be made in detail to the present preferred embodiments of the invention, examples of which are illustrated in the accompanying drawings. Wherever possible, the same reference numbers are used in the drawings and the description to refer to the same or like parts.

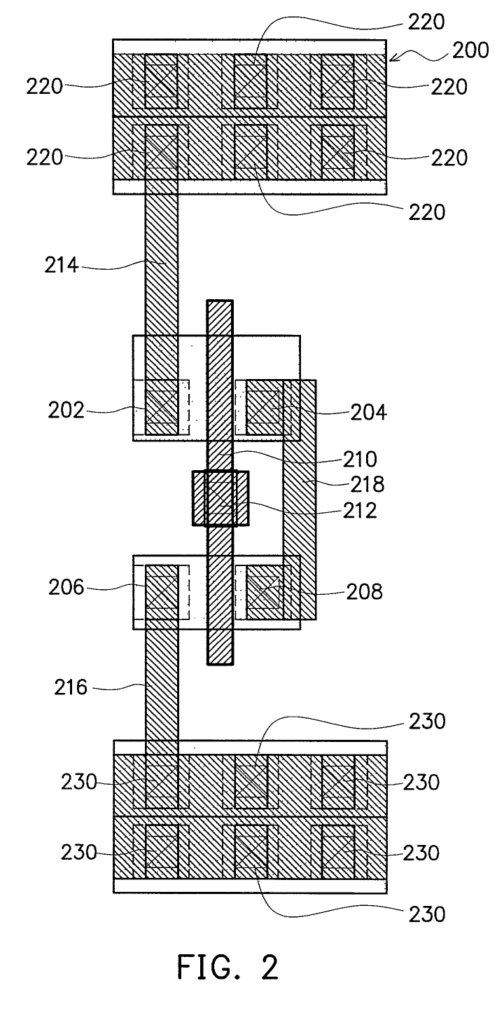

Referring to FIG. 2, a first inverter cell 200, according to one embodiment of the present invention, comprising a PMOS structure, for example, having a gate, wherein the gate is surrounded by an N well. A contact 202 is in contact with the source region and a contact 204 is in contact with the drain region of the PMOS structure. A NMOS structure, for example, having a gate, wherein the gate is surrounded by a P well. A contact 206 is in contact with the source region and a contact 208 is in contact with the drain region of the NMOS. The gate of the PMOS and the gate of the NMOS are connected together by a poly line 210 through a via 212. The source of the PMOS is connected to the power line VDD by a metal line 214 and the source of the NMOS is connected to the power line GND by a metal line 216. The drains of both the NMOS and the PMOS are connected by a metal line 218. Ports 220 is in contact with the power line VDD and ports 230 is in contact with the power line GND.

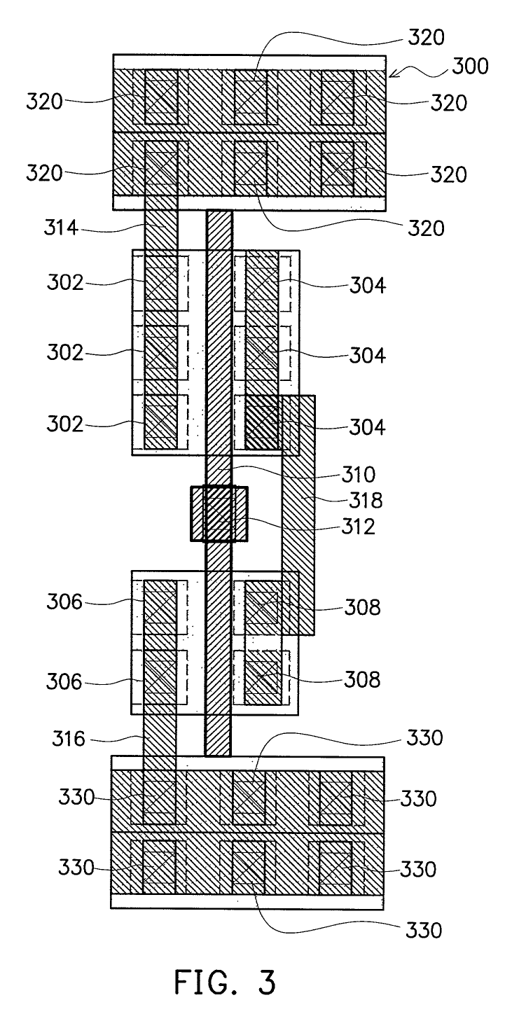

Referring to FIG. 3, a second inverter cell 300, according to one embodiment of the present invention, comprising a PMOS structure, for example, having a gate, wherein the gate is surrounded by an N well. Contacts 302 are in contact with the drain region and contacts 304 are in contact with the source region of the PMOS structure. A NMOS structure, for example, having a gate, wherein the gate is surrounded by a P well. Contacts 306 are in contact with the drain region and contacts 308 are in contact with the source region of the NMOS. The gate of the PMOS and the gate of the NMOS are connected together by a poly line 310 through a via 312. The source of the PMOS is connected to the power line VDD by a metal line 314 and the source of the NMOS is connected to the power line GND by a metal line 316. The drains of both the NMOS and the PMOS are connected by a metal line 318. Ports 320 is in contact with the power line VDD and ports 330 is in contact with the power line GND.

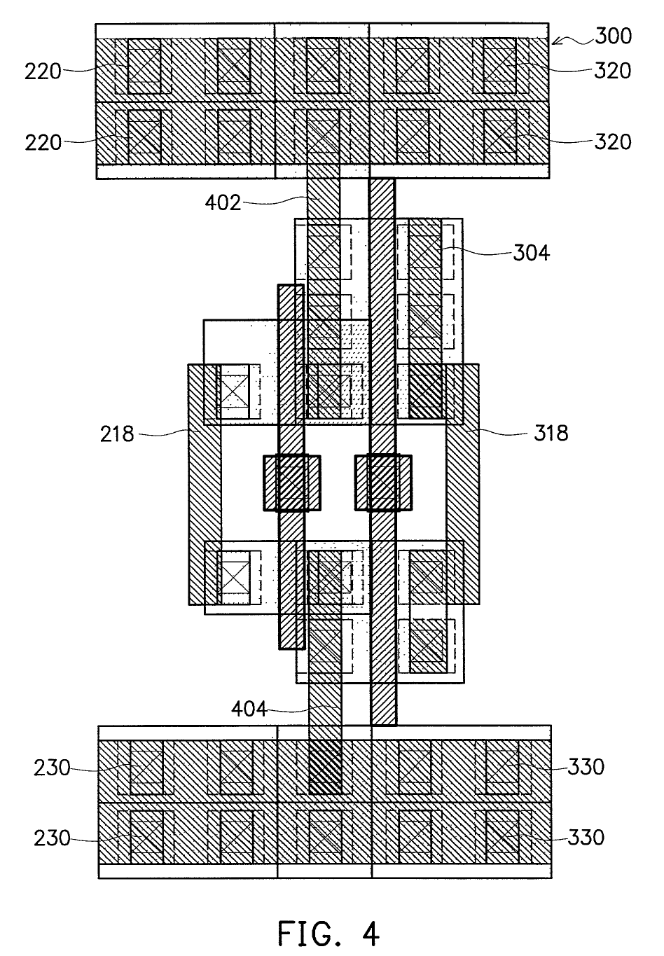

Referring to FIG. 4, the first inverter cell and the second inverter cell are partially overlapped in such a way that the metal line 214 and 216 of the first inverter cell overlaps and in contact with the metal line 314 and 316 of the second inverter cell respectively as shown in FIG. 4 by the numerals 402 and 404 respectively. Although the best mode utilizes two inverter cells to show the interconnection between the two inverter cells, it is to be understood that more than two inverter cells may be interconnected by method of the present invention to practice the present invention. Although the best mode of the present invention shows a method for interconnecting two inverter cells, it is to be understood that other cells such as OR, NAND, NOR, AND, XOR, and like logical cells with an array of logic gate sizes, may be interconnected by method of the present invention to practice the present invention. The cells are positioned so as to minimize the block size so that the total area of the layout can be minimized.

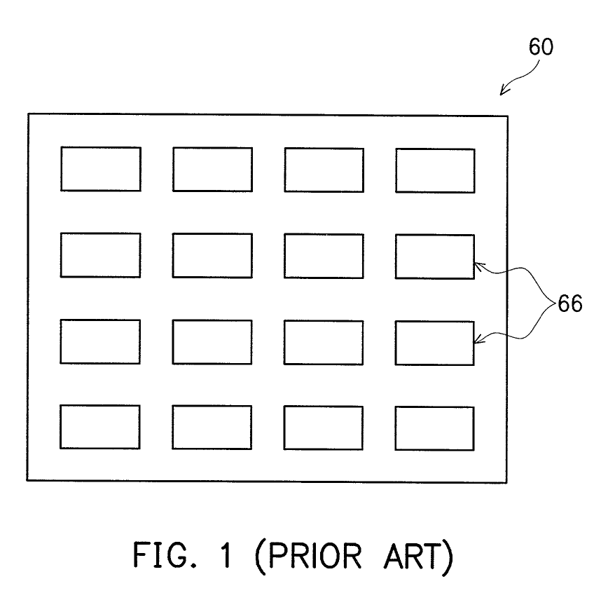

FIG. 1, shows a conventional cells arrangement scheme, the cells are arranged next to each other without overlapping and the cell to cell connections are made by interconnect wires (not shown). The space in between the power lines VDD of a first cell and the second cell which is positioned adjacent to the first cell is called a “line to line pitch”. In a typical conventional cell arrangement scheme, for example, the line to line pitch width along the X direction is about 0.8μ. Therefore by following the merged power scheme of the present invention, for example, at least 0.8μ layout space between two adjacent cells is conserved and utilized.

After floor planning and placement according to the present invention, the routing and manufacture of IC may be carried out according to the traditional scheme.

One aspect of the present invention is that since the interconnection between the cells by using interconnect wires is eliminated by merging the VDD and GND power lines between the adjacent cells, therefore, the replacement of cells can be implemented easily and in a short time. In the event the placement may produce an unroutable layout, the defective cell(s) can be easily replaced. Therefore the whole the chip need not be to be replaced or re-partitioned by removing defective block(s) and replacing with new block(s) before another routing is attempted. Therefore, the through-put and the cost is substantially increased.

Another aspect of the present invention is that since the wire connection between the cells is eliminated by merging the VDD and GND power lines between the adjacent cells, therefore, time needed to make or design the wire connection between cells which was required in the traditional scheme can be avoided. Therefore, the cost and through-put can be further increased.

It is to be understood by those skilled in the art that because the cells are partially overlapped, therefore, the total area of the layout can be substantially reduced.

It is to be understood by those skilled in the art that because the wire interconnections between the cells are eliminated, therefore the complexity of making the wire connection between cells can be effectively eliminated.

It is to be understood by those skilled in the art that because the complexity of making the wire interconnections between the cells are eliminated, therefore the risk of faulty connections between the cells can be eliminated, thus the yield can be substantially increased.

It is to be understood by those skilled in the art that because the wire connections between the cells are eliminated, therefore the time and the total wire length can be substantially reduced. Therefore, the overall IC design time can be substantially reduced. Therefore the through-put can be substantially increased. Therefore the overall cost of the IC fabrication can be substantially reduced.

While the best mode utilizes two inverter cells for showing the interconnection, it should be understood that more than two inverter cells thereof may be used to practice the present invention.

While the best mode utilizes inverter cells for showing the interconnection between the cells, it should be understood that other cells comprising OR, NAND, NOR, AND, XOR, and like logical cells with an array of logic gates thereof may be used to practice the present invention.

Although illustrated and described above with reference to certain specific embodiments, the present invention is nevertheless not intended to be limited to the details shown. Rather, various modifications may be made in the details within the scope and range of equivalents of the claims and without departing from the spirit of the invention.

While the invention has been described in conjunction with a specific best mode, it is to be understood that many alternatives, modifications, and variations will be apparent to those skilled in the art in light of the a foregoing description. Accordingly, it is intended to embrace all such alternatives, modifications, and variations which fall within the spirit and scope of the included claims. All matters set forth herein or shown in the accompanying drawings are to be interpreted in an illustrative and non-limiting sense.

What is claimed is:

1. A physical placement method for a highest fitness cell placement for an integrated circuit chip design, comprising:
providing a first cell comprising a PMOS and a NMOS, wherein the source of the PMOS is connected with a power line VDD by a first metal line, the source of the NMOS is connected to a power line GND by a second metal line, the drains of the PMOS and NMOS connected together by a third metal line, and the gate of the PMOS and the NMOS are connected together by a poly line;
providing a second cell comprising a PMOS and a NMOS, wherein the source of the PMOS is connected with a power line VDD by a first metal line, the source of the NMOS is connected to a power line GND by a second metal line, the drains of the PMOS and NMOS connected together by a third metal line, and the gate of the PMOS and the NMOS are connected together by a poly line;
partially overlapping the first cell and the second cell, wherein the first and the second metal line of the first cell overlaps and in contact with the first and the second metal line of the second cell respectively; and
Performing a partitioning and routing process.

2. The method according to claim 1, wherein the first cell and the second cell include an inverter.

3. The method according to claim 1, wherein the first cell and the second cell comprises fundamental logic gates such as OR, NAND, NOR, AND, and XOR.

4. A structure of a highest fitness cell placement arrangement for an integrated circuit chip design, comprising:
a first cell comprising a PMOS and a NMOS, wherein the source of the PMOS is connected with a power line VDD by a first metal line, the source of the NMOS is connected to a power line GND by a second metal line, the drains of the PMOS and NMOS connected together by a third metal line, and the gate of the PMOS and the NMOS are connected together by a poly line; and
a second cell comprising a PMOS and a NMOS, wherein the source of the PMOS is connected with a power line VDD by a first metal line, the source of the NMOS is connected to a power line GND by a second metal line, the drains of the PMOS and NMOS connected together by a third metal line, and the gate of the PMOS and the NMOS are connected together by a poly line, the second cell partially overlapped with the first cell in a such a way that the first and the second metal line of the first cell is overlapped and in contact with the first and the second metal line of the second cell respectively.

5. The structure according to claim 4, wherein the first cell and the second cell include an inverter.

6. The structure according to claim 4, wherein the first cell and the second cell include fundamental logic gates such as OR, NAND, NOR, AND, and XOR.
